(19) United States
(12) Patent Application Publication
(10) Pub. No.: US 2023/0071812 A1
(43) Pub. Date: Mar. 9, 2023

(54) SEMICONDUCTOR PACKAGE

(71) Applicant: SAMSUNG ELECTRONICS CO., LTD., SUWON-SI (KR)

(72) Inventors: Jaegwon JANG, Hwaseong-si (KR); Kyounglim SUK, Suwon-si (KR); Inhyung SONG, Cheonan-si (KR)

(21) Appl. No.: 17/846,245

(22) Filed: Jun. 22, 2022

(30) Foreign Application Priority Data
Sep. 3, 2021 (KR) 10-2021-0117606

(51) Int. Cl. H01L 25/065; H01L 25/10; H01L 23/498; H01L 23/00

(52) U.S. Cl. CPC H01L 25/0657; H01L 25/105; H01L 23/49816; H01L 23/49838; H01L 24/08; H01L 24/16; H01L 25/16

(57) ABSTRACT

A semiconductor package includes a substrate including a redistribution layer, a chip structure including a first semiconductor chip disposed on the substrate and including a first through-electrode, a second semiconductor chip disposed on the first semiconductor chip and electrically connected to the first semiconductor chip by the first through-electrode, and a first encapsulant at least partially surrounding the second semiconductor chip. A first connection bump disposed between the substrate and the chip structure and electrically connects the first through-electrode to the redistribution layer, a second connection bump disposed below the substrate and electrically connects to the redistribution layer, and a second encapsulant e the chip structure on the substrate. The first semiconductor chip is connected to and faces the second semiconductor chip.

### CROSS-REFERENCE TO RELATED APPLICATION(S)

This application claims priority under 35 USC § 119 to Korean Patent Application No. 10-2021-0117606 filed on Sep. 3, 2021 in the Korean Intellectual Property Office, the disclosure of which is incorporated by reference herein in its entirety.

### TECHNICAL FIELD

The present inventive concept relates to a semiconductor package.

### DISCUSSION OF THE RELATED ART

Semiconductor devices include semiconductor chips in order to implement functionality in the devices, such as general processors, memory, and power management. In an effort to miniaturize the devices, semiconductor chips have been combined into larger system-on-chip or system-in-package structures. These structures include 2.5D structures, in which the chips are disposed adjacent to each other and connected with each other using a lateral substrate, as well as 3D structures, in which chips are stacked on top of one another and connected vertically, such as through internal through vias and external wiring. In some cases, however, chips stacks with several layers and excessive thickness may not be readily mounted on a substrate during manufacturing.

### SUMMARY

An aspect of the present inventive concept is to provide a semiconductor package including a chip structure in which a plurality of semiconductor chips are stacked.

According to an aspect of the present inventive concept, a semiconductor package includes a substrate including a redistribution layer, a chip structure including a first semiconductor chip disposed on the substrate and including a first through-electrode, and further including a second semiconductor chip disposed on the first semiconductor chip and electrically connected to the first semiconductor chip by the first through-electrode, and further including a first encapsulant surrounding the second semiconductor chip. The semiconductor package also includes a first connection bump disposed between the substrate and the chip structure and electrically connecting the first through-electrode to the redistribution layer, a second connection bump disposed below the substrate and electrically connected to the redistribution layer, and a second encapsulant encapsulating the chip structure on the substrate. The first semiconductor chip has a first upper surface on which a first upper pad is disposed and a first lower surface on which a first lower pad electrically connected to the first upper pad through the first through- electrode is disposed, the second semiconductor chip has a second lower surface on which a second lower pad electrically connected to the first upper pad is disposed, and the second lower surface of the second semiconductor chip is in direct contact with the first upper surface of the first semiconductor chip.

According to another aspect of the present inventive concept, a semiconductor package includes a substrate including a redistribution layer, a chip structure including a plurality of semiconductor chips disposed on an upper surface of the substrate and stacked in a vertical direction perpendicular to the upper surface of the substrate, and a first encapsulant surrounding a side surface of one or more of the semiconductor chips, a connection bump disposed between the substrate and the chip structure and electrically connecting the plurality of semiconductor chips to the redistribution layer, and a second encapsulant encapsulating the chip structure on the substrate. The chip structure has a lower surface spaced apart from the upper surface of the substrate, and the second encapsulant fills a space between the lower surface of the chip structure and the upper surface of the substrate and surrounds a side surface of the connection bump.

According to another aspect of the present inventive concept, a semiconductor package includes a substrate including a first redistribution layer, a chip structure including a plurality of semiconductor chips disposed on an upper surface of the substrate and stacked in a direction, perpendicular to the upper surface of the substrate, and a first encapsulant surrounding a side surface of one or more of the semiconductor chips, a connection bump disposed between the substrate and the chip structure and electrically connecting the plurality of semiconductor chips to the redistribution layer, a second encapsulant covering an upper surface and a lower surface of the chip structure, a redistribution structure including an insulating layer disposed on the second encapsulant, and further including a second redistribution layer on the insulating layer, and a connection structure penetrating through the second encapsulant to electrically connect the first redistribution layer to the second redistribution layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view that illustrates a semiconductor package according to an embodiment of the present inventive concept, and FIG. 1B is a plan view that illustrates a cross-section taken along line I-I′ of FIG. 1A;

FIG. 2 is a cross-sectional view that illustrates a semiconductor package according to an embodiment of the present inventive concept;

FIG. 3 is a cross-sectional view that illustrates a semiconductor package according to an embodiment of the present inventive concept;

FIG. 4 is a cross-sectional view that illustrates a semiconductor package according to an embodiment of the present inventive concept;

FIG. 5A is a cross-sectional view that illustrates a semiconductor package according to an embodiment of the present inventive concept, and FIG. 5B is a plan view that illustrates a cross-section taken along line II-II′ of FIG. 5A;

FIG. 6A is a cross-sectional view that illustrates a semiconductor package according to an embodiment of the present inventive concept, and FIG. 6B is a plan view that illustrates a cross-section taken along line of FIG. 6A;

FIG. 7 is a cross-sectional view that illustrates a semiconductor package according to an embodiment of the present inventive concept;

FIGS. 8A to 8C are cross-sectional views that illustrate a manufacturing process of a chip structure applied to a semiconductor package according to a process sequence of an example embodiment; and

FIGS. 9A to 9D are cross-sectional views that illustrate a manufacturing process of a semiconductor package according to a process sequence of an example embodiment.

### DETAILED DESCRIPTION

Hereinafter, example embodiments of the present inventive concept will be described with reference to the accompanying drawings. Like reference symbols in the drawings may denote like elements, and to the extent that a description of an element has been omitted, it may be understood that the element is at least similar to corresponding elements that are described elsewhere in the specification.

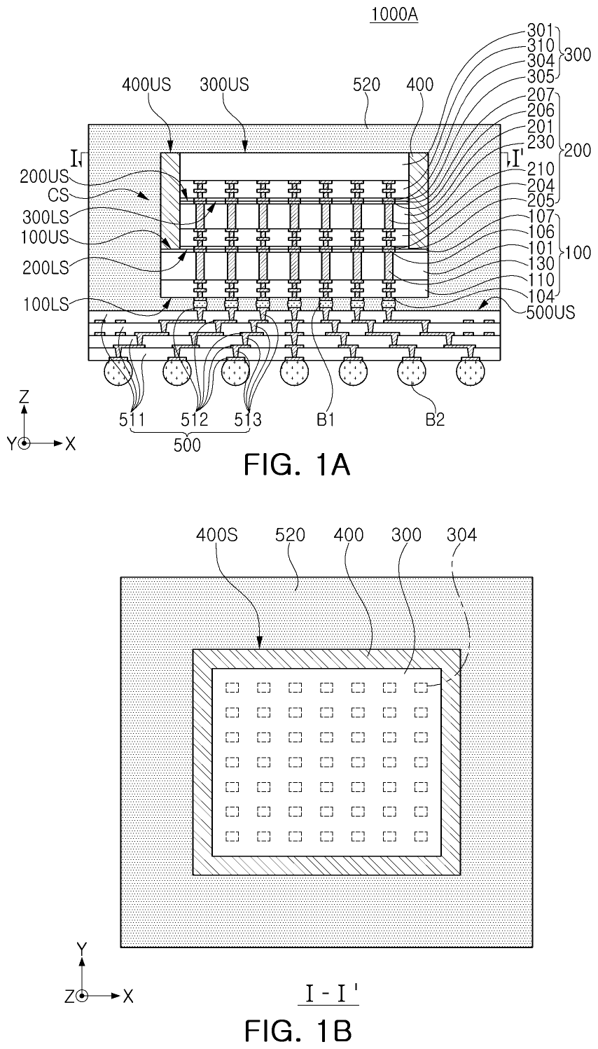

FIG. 1A is a cross-sectional view that illustrates a semiconductor package 1000A according to an embodiment of the present inventive concept, and FIG. 1B is a plan view that illustrates a cross-section taken along line I-I′ of FIG. 1A.

Referring to FIGS. 1A and 1B, a semiconductor package 1000A according to an embodiment may include a chip structure CS and a substrate 500 on which the chip structure CS is mounted. Here, in the chip structure CS, two or more semiconductor chips (e.g., 100 and 200) are stacked in a vertical direction (Z-axis direction) on a mounting surface of the substrate 500, and the semiconductor chips (e.g., 100, and 200) may be electrically connected to each other by a through-silicon via (TSV), such as through-electrodes 130 and 230.

In order to mount the chip structure CS on a main board of an electronic component, it is necessary to package the chip structure CS in fan-out form. A fan-out form may allow a relatively small die size for the chip, without restricting the number of connection lines to the chip, and may provide improved thermal and electrical characteristics.

In a comparative example, when a redistribution circuit is integrally formed on a lower surface of the chip structure CS to which a lower pad 104 of the lowermost semiconductor chip 100 is exposed, after upper and side surfaces of the chip structure CS are first sealed, undulation occurs due to a thickness of the chip structure CS, making it difficult to form a fine-pitch redistribution circuit. For example, in the comparative example, it may be difficult to form a redistribution circuit onto the chip structure due to the thickness of the chip structure.

Meanwhile, according to the present inventive concept, by mounting the chip structure CS having a significant thickness on the separately manufactured substrate 500 in a flip-chip manner, the chip structure CS may be redistributed through a fine-pitch redistribution circuit and the yield of the semiconductor package 1000A including the chip structure CS may be increased. Accordingly, the semiconductor package 1000A according to an example embodiment may further include a first connection bump B1 electrically connecting the chip structure CS to the redistribution layer 512 of the substrate 500 and a second connection bump B2 serving as an external connection terminal on a lower surface of the substrate 500. For example, the semiconductor package 1000A may further include a second encapsulant 520 sealing the chip structure CS on the substrate 500. In this case, the chip structure CS may have a lower surface spaced apart from an upper surface 500US of the substrate 500, and the second encapsulant 520 may fill between a lower surface of the chip structure CS and the upper surface 500US of the substrate and surround side surface(s) of the first connection bump B I. The lower surface of the chip structure CS may be understood as designating the same surface as a lower surface 100LS of the lowermost semiconductor chip, for example, a first semiconductor chip 100.

Hereinafter, each element constituting the semiconductor package 1000A according to an example embodiment will be described in detail.

The chip structure CS may be disposed on the upper surface 500US of the substrate 500 and may include the semiconductor chips 100, 200, and 300 stacked in a direction perpendicular to the upper surface 500US of the substrate 500 (e.g. the Z-axis direction), and a first encapsulant 400 surrounding side surface(s) of at least some of the semiconductor chips 100, 200, and 300. The chip structure CS may have a lower surface facing the substrate 500, an upper surface opposite to the lower surface, and side surface(s) between the lower surface and the upper surface. The lower surface, the upper surface, and the side surface of the chip structure CS may be covered by the second encapsulant 520. For example, the first encapsulant 400 may expose an upper surface 300US of the uppermost semiconductor chip 300, and the upper surface of the chip structure CS may include the upper surface 400US of the first encapsulant 400 and the upper surface 300US of the uppermost semiconductor chip 300. The chip structure CS may have a height ranging from about 200 μm or more. For example, in various embodiments, the height of the chip structure CS may be about 200 μm to about 1000 μm, about 200 μm to 600 μm, and/or about 200 μm to 300 μm, in a direction perpendicular to the upper surface 500US of the substrate 500. For example, the chip structure CS may have a height at which it is difficult to directly form a redistribution circuit on the lower surface thereof, and the height of the chip structure CS may refer to a distance from the lower surface 100LS of the lowermost semiconductor chip 100 to the uppermost surface 300US of the uppermost semiconductor chip 300. The chip structure CS may include more or fewer semiconductor chips than illustrated in the drawings. For example, the chip structure CS may include two or four semiconductor chips stacked in a vertical direction (Z-axis direction). The first encapsulant 400 may include an insulating material. The insulating material may include a thermosetting resin such as an epoxy resin, a thermoplastic resin such as polyimide, or a resin obtained by impregnating these resins with an inorganic filler and/or glass fiber (glass Cloth or glass fabric), for example, a prepreg, Ajinomoto build-up film (ABF), FR-4, bismaleimide tiazine (BT), and epoxy molding compound (EMC).

The first semiconductor chip 100 may have a width greater than a width of the second semiconductor chip 200 and the third semiconductor chip 300 in a direction (e.g., in an X-axis direction) parallel to the upper surface 500US of the substrate 500. In this case, the first encapsulant 400 is formed to surround side surface(s) of each of the second and third semiconductor chips 200 and 300 on the first semiconductor chip 100. The first encapsulant 400 may be in contact with at least a portion of an upper surface 100US and side surface(s) of each of the second and third semiconductor chips 200 and 300, but the present inventive concept is not limited thereto.

At least some semiconductor chips 100 and 200 of the semiconductor chips 100, 200, and 300 may include through-electrodes 130 and 230, and the semiconductor chips 100, 200 and 300 may be electrically connected to each other through the through-electrodes 130 and 230. For example, the first and second semiconductor chips 100 and 200 disposed under the third semiconductor chip 300 include first and second through-electrodes 130 and 230, respectively, and the third semiconductor chip 300 might not include a through-electrode. The first to third semiconductor chips 100, 200, and 300 may be electrically connected to each other through the first and second through-electrodes 130 and 230. The semiconductor chips 100, 200, and 300 may be chiplets constituting a multi-chip module (MCM). The semiconductor chips 100, 200, and 300 may include an I/O chip, a central processor (CPU), a graphics processor (GPU), a field programmable gate array (FPGA), a digital signal processor (DSP), an encryption processor, a microprocessor, a microcontroller, an analog-to-digital converter (ADC), and the like, but are not limited thereto. For example, the chip structure CS may include first to third semiconductor chips 100, 200, and 300, where the first semiconductor chip 100 is a GPU chip, the second semiconductor chip 200 is a CPU chip, and the third semiconductor chip 300 may be an FPGA chip.

The first semiconductor chip 100 may include a semiconductor layer 101, a device layer 110, a lower pad 104, and an upper pad 106. For example, the first semiconductor chip 100 may further include a first upper dielectric layer 107 surrounding the upper pad 106 (e.g., surrounding lateral sides of the upper pad 106) and providing the first upper surface 100US in contact with the second semiconductor chip 200 and a first through-electrode 130 electrically connecting the lower pad 104 to the upper pad 106.

The semiconductor layer 101 may include, for example, a semiconductor element such as silicon or germanium. (Ge) and/or may include a compound semiconductor such as silicon carbide (SiC), gallium arsenide (GaAs), indium arsenide (InAs), or indium phosphide. The semiconductor layer 101 may have a silicon on insulator (SOI) structure. The semiconductor layer 101 may include a conductive region, for example, a well which is doped with an impurity or a structure which is doped with an impurity. The semiconductor layer 101 may include various device isolation structures such as a shallow trench isolation (STI) structure.

The device layer 110 may be disposed on a lower surface of the semiconductor layer 101 and may include various types of devices. For example, the device layer 110 may include a field effect transistor (FET) such as a planar FET or a FinFET, a memory device such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), and/or a resistive random access memory (RRAM). The device layer 110 may additionally or alternatively include a logic element such as an AND, an OR, or a NOT, various active elements and/or passive elements such as a system large scale integration (LSI), a CMOS imaging sensor (CIS), a micro-electro-mechanical system (MEMS).

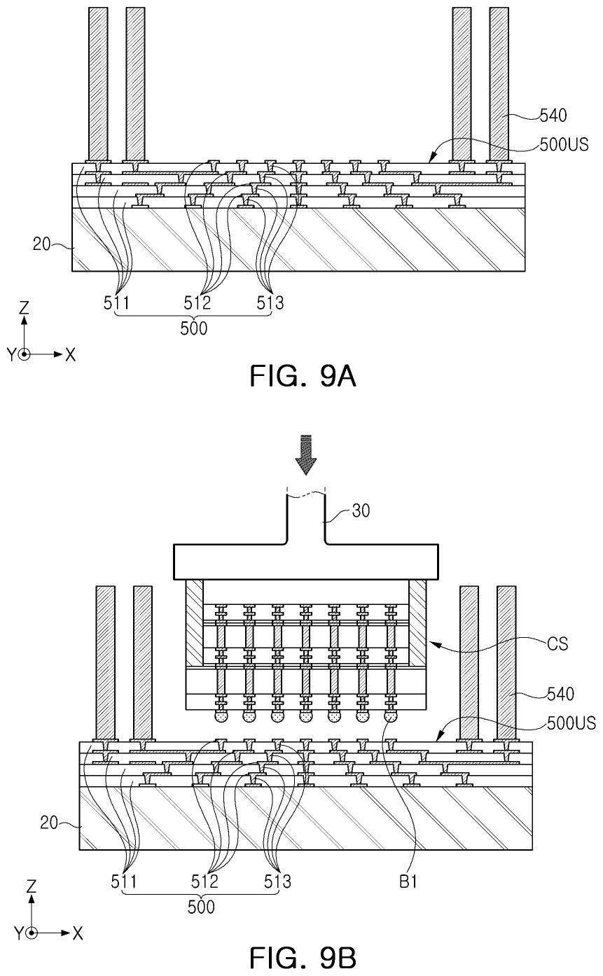

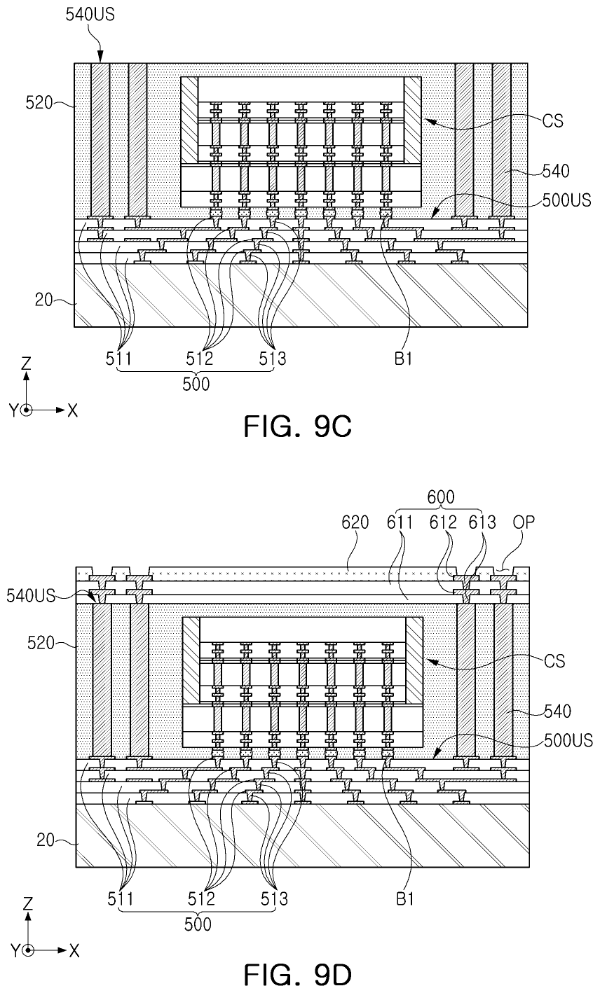

The device layer 110 may include an interlayer insulating layer (e.g. ‘111’ in FIG. 9A) and a multilayer wiring layer (e.g. ‘112’ in FIG. 9A) on the devices described above. The interlayer insulating layer may include silicon oxide or silicon nitride. The multilayer wiring layer may include a multilayer wiring and/or a vertical contact. The multilayer wiring layer may connect devices of the device layer 110 to each other, may connect the devices to a conductive region of the semiconductor layer 101, and/or may connect the devices to the first through- electrode 130 and/or the lower pad 104.

The first lower pad 104 and the first upper pad 106 may include at least one of, for example, aluminum (Al), copper (Cu), nickel (Ni), tungsten (W), platinum (Pt), and gold (Au). The first lower pad 104 may be disposed below the device layer 110, and the first upper pad 106 may be disposed on the semiconductor layer 101. Although not shown in the drawings, an upper protective layer surrounding the first through-electrode 130 and electrically insulating the first upper pad 106 and the semiconductor layer 101 may be disposed between the first upper pad 106 and the semiconductor layer 101. The upper protective layer may be formed of an insulating layer such as a silicon oxide film, a silicon nitride film, and/or a silicon oxynitride film, but a material of the upper protective layer is not limited thereto. For example, the upper protective layer may be formed of a polymer such as polyimide. Meanwhile, the first upper dielectric layer 107 may surround side surface(s) of the first upper pad 106, and may include an insulating material, for example, silicon oxide and the like, that may be combined with the second lower dielectric layer 205 of the second semiconductor chip 200.

The first through-electrode 130 may penetrate through the semiconductor layer 101 in the vertical direction (Z-direction) and may provide an electrical path connecting the first upper pad 106 to the first lower pad 104. The first through-electrode 130 may include a conductive plug and a barrier layer surrounding the conductive plug. The conductive plug may include a metal material, for example, tungsten (W), titanium (Ti), aluminum (Al), and/or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbide film, a polymer, and/or a combination thereof. A conductive barrier film may be disposed between the insulating barrier film and the conductive plug. The conductive barrier film may include, for example, a metal compound such as tungsten nitride (WN), titanium nitride (TiN), and/or tantalum nitride (TaN). The barrier film may be formed by a PVD process or a CVD process.

The second semiconductor chip 200 may be stacked on the first semiconductor chip 100 and may include a semiconductor layer 201, a device layer 210, a lower pad 204, an upper pad 206, and a second through-electrode 230. For example, the second semiconductor chip 200 may further include a second lower dielectric layer 205 surrounding the second lower pad 204 and providing a second lower surface 200LS and a second upper dielectric layer 207 surrounding the second upper pad 206 and providing a second upper surface 200US. The second lower surface 200LS may be in direct contact with the first upper surface 100US of the first semiconductor chip 100.

Each element of the second semiconductor chip 200 has characteristics which are the same as or similar to those of the elements of the first semiconductor chip 100 corresponding thereto, and thus, a redundant description thereof is omitted. As described above, the chip structure CS may include four or more semiconductor chips, and in this case, the semiconductor chips may be further stacked between the third semiconductor chip 300 and the second semiconductor chip 200.

The third semiconductor chip 300 may be stacked on the second semiconductor chip 200, and may include a semiconductor layer 301, a device layer 310, a lower pad 304, and an upper pad 306. For example, the third semiconductor chip 300 may further include a third lower dielectric layer 305 surrounding the third lower pad 304 and providing a third lower surface 300LS. The third lower surface 300LS may be in direct contact with the second upper surface 200US of the second semiconductor chip 200. Since each element of the third semiconductor chip 300 has the same or similar characteristics as those of the corresponding elements of the first semiconductor chip 100, a redundant description thereof is omitted.

In an embodiment, the semiconductor chips 100, 200, and 300 may have a structure in which an upper surface and a lower surface of each of the semiconductor chips are in close contact with each other (for example, without a separate connection member (e.g., metal fillar, solder bump, etc.). This close contact structure may be referred to as hybrid bonding, direct bonding, etc. For example, the first semiconductor chip 100 may have a first upper surface 100US on which the first upper pad 106 is disposed and a first lower surface 100LS electrically connected to the first upper pad 106 which allows the first lower pad 104 to be disposed thereon. The second semiconductor chip 200 may have a second lower surface 200LS on which the second lower pad 204 electrically connected to the first upper pad 106 is disposed, and the second lower surface may be in direct contact with the first upper surface 100US. Here, a direct bonding structure may be formed between the second lower surface 200LS and the first upper surface 100US through a thermocompression process. For example, Cu to Cu bonding may be formed between the first upper pad 105 and the second lower pad 204, and oxide to oxide bonding may be formed between the first upper dielectric layer 107 and the second lower dielectric layer 205 surrounding the first upper pad 106 and the second lower pad 204. Also, the same or similar bonding structure may be formed between the second semiconductor chip 200 and the third semiconductor chip 300.

The substrate 500 has an upper surface 500US on which the chip structure CS is mounted, and may include an insulating layer 511, a redistribution layer 512, and a redistribution via 513. A connection bump B2 capable of electrically connecting the redistribution layer 512 to an external device may be disposed on a lower surface of the substrate 500.

The insulating layer 511 may include a plurality of insulating layers 511 stacked in a vertical direction (a Z-direction). The insulating layer 511 may include an insulating material. The insulating material may include a thermosetting resin such as an epoxy resin, a thermoplastic resin such as polyimide, and/or a resin obtained by impregnating these resins with inorganic fillers and/or glass fibers, for example, prepreg, ABF, FR-4, BT. In addition, the insulating layer 511 may include a photosensitive resin such as a photoimageable dielectric (PID) resin. In this case, the insulating layer 511 may be thinner, and the redistribution via 113 may be formed more finely. When the insulating layer 511 includes multiple layers, the multiple layers may include the same material or different materials, and a boundary between the insulating layers 511 of different levels might not be apparent depending on the process used to form the insulating layers 511.

The redistribution layer 512 may be disposed on the insulating layer 511. The redistribution layer 512 may redistribute a connection terminal of the chip structure CS, for example, the lower pad(s) 104 of the first semiconductor chip 100, to the fan-out region. The fan-out region refers to a region that does not overlap the chip structure CS in the vertical direction (Z-direction). The redistribution layer 512 may include a metal material including, for example, copper (Cu), aluminum (Al), silver (Ag), tin (Sn), gold (Au), nickel (Ni), lead (Pb), and/or titanium (Ti), and/or alloys thereof. The redistribution layer 512 may perform various functions according to a design. For example, the redistribution layer 512 may include a ground (GND) pattern, a power (PWR) pattern, and a signal (S) pattern. The signal (S) pattern includes various signals, e.g., a data signal, etc., other than the ground (GND) pattern and the power (PWR) pattern.

The redistribution via 513 may be electrically connected to the redistribution layer 512 through the insulating layer 511. For example, the redistribution via 513 may interconnect the redistribution layers 512 on different levels. The redistribution via 513 may include a signal via, a ground via, and a power via. The redistribution via 513 may include a metal material, for example, copper (Cu), aluminum (Al), silver (Ag), tin (Sn), gold (Au), nickel (Ni), lead (Pb), and/or titanium (Ti), and/or alloys thereof. The redistribution via 513 may be a filled via formed by filling a via hole with a metal material or a conformal via in which a metal material is formed on an inner wall of the via hole 113h.

The second encapsulant 520 may encapsulate at least a portion of the chip structure CS on the substrate 500. The second encapsulant 520 may include, for example, a thermosetting resin such as an epoxy resin, a thermoplastic resin such as polyimide, and/or a prepreg, glass fiber, ABF, FR-4, BT, EMC and the like including an inorganic filler or/and glass fiber. The second encapsulant 520 may include the same type of insulating material as that of the first encapsulant 400, but is not limited thereto.

According to the present inventive concepts, in order to increase the yield of the semiconductor package 1000A including the chip structure CS and redistribute the chip structure CS through a fine-pitch redistribution circuit, the chip structure CS having a significant thickness is mounted in a flip chip manner on the substrate 500 which is separately manufactured. Accordingly, the second encapsulant 520 may fill a space between the chip structure CS and the upper surface 500US of the substrate 500, and may be in contact with all of the lower surface, the side surface, and the upper surface of the chip structure CS. Also, the second encapsulant 520 may have a boundary with the first encapsulant 400, regardless of the type of insulating material. For example, a boundary between the second encapsulant and the first encapsulant may be apparent even though the second encapsulant includes the same type of insulating material, e.g., EMC. For example, the second encapsulant 520 may have an interface in contact with the upper surface 40005 and the side surface (‘400S’ in FIG. 1B) of the first encapsulant 400.

The first connection bump B1 and the second connection bump B2 may include a low melting point metal, for example, tin (Sn) and/or an alloy (Sn—Ag—Cu) including tin (Sn). The first connection bump B1 may be disposed between the substrate 500 and the chip structure CS, and may electrically connect the chip structure CS to the redistribution layer 512 of the substrate 500. The first connection bump B1 and the second connection bump B2 may have a land, ball, or pin shape. For example, the first connection bump B1 and the second connection bump B2 may be copper pillars or solder balls.

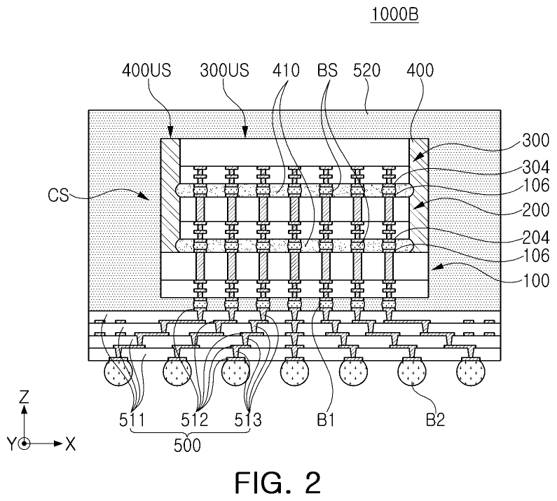

FIG. 2 is a cross-sectional view that illustrates a semiconductor package 1000B according to an embodiment of the present inventive concept.

Referring to FIG. 2, the semiconductor package 1000B according to an example embodiment may be understood as having characteristics the same as or similar to those of the semiconductor package 1000A illustrated in FIG. 1A, except that a bump structure BS and an adhesive film 410 are interposed between the semiconductor chips 100, 200, and 300. Accordingly, redundant descriptions with reference to FIGS. 1A and 1B will be omitted.

The bump structure BS may be disposed between the first upper pad 106 and the second lower pad 204 and between the second upper pad 206 and the third lower pad 304 to electrically connect the pads. The bump structure BS may include, for example, solder, and may include both a pillar and a solder according to an embodiment. The pillar may have a cylindrical or polygonal column shape such as a square or octagonal column and may include, for example, nickel (Ni), copper (Cu), palladium (Pd), platinum (Pt), gold (Au), and/or a combination thereof. Solder has a spherical or ball shape, for example, tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc.

The adhesive film 410 may be disposed between the first semiconductor chip 100 and the second semiconductor chip 200 and between the second semiconductor chip 200 and the third semiconductor chip 300. The adhesive film 410 may be a non-conductive film (NCF), but is not limited thereto, and adheres between the semiconductor chips 100, 200, and 300. The adhesive film 410 may include any kind of polymer films capable of bonding the semiconductor chips 100, 200, and 300 therebetween and capable of electrically insulating the first connection bumps B1 and/or the second connection bumps B2.

The chip structure CS of the present embodiment may have a relatively large thickness compared to the chip structure CS of the embodiment of FIG. 1A. However, according to the present inventive concept, by mounting the relatively thick chip structure CS to a separately manufactured substrate, the chip structure CS may be redistributed through the fine-pitch redistribution circuit, and the yield of the semiconductor package 1000B including the chip structure CS may be increased.

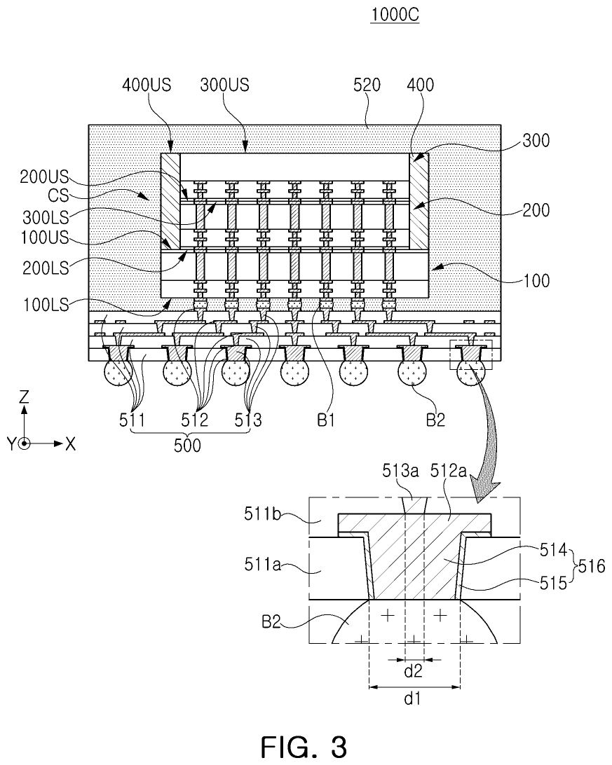

FIG. 3 is a cross-sectional view that illustrates a semiconductor package 1000C according to an embodiment of the present inventive concept.

Referring to FIG. 3, the semiconductor package 1000C according to an embodiment may have characteristics the same as or similar to those of the semiconductor packages 1000A and 1000B of FIGS. I A and 2, except that an under-bump metallization (UBM) structure 516 is connected to the second connection bump B2 under the substrate 500. For example, the substrate 500 may further include the lowermost insulating layer 511a positioned on the second connection bump B2 and a UBM structure 516 electrically connecting the lowermost redistribution layer 512a on the lowermost insulating layer 511a to the second connection bump B2. The lowermost redistribution layer 512a may be covered by the upper insulating layer 511b and may be electrically connected to another redistribution layer 512 through the lowermost redistribution via 513a penetrating through the upper insulating layer 511b.

The UBM structure 516 of the present embodiment may include a UBM via 514 penetrating through the lowermost insulating layer 511a and a barrier layer 515 disposed between a side of the UBM via 514 and the lowermost insulating layer 511a. The UBM via 514 may have a width dl that is greater than a width d2 of the lowermost redistribution via 513a, and thus connection reliability with the second connection bump B2 may be secured. In addition, the barrier layer 515 may increase adhesion between the UBM via 514 and the lowermost insulating layer 511a and prevent peeling of the lowermost insulating layer 511a and secure reliability of the UBM structure 516.

The barrier layer 515 may be disposed between the lowermost insulating layer 511a, the redistribution layer 112a, and the UBM via 514. For example, the barrier layer 515 may have a shape extending along a lower surface of the redistribution layer 112a and side surface(s) of the UBM via 514. The barrier layer 515 may include a metallic material, for example, copper (Cu), aluminum (Al), silver (Ag), tin (Sn), gold (Au), nickel (Ni), lead (Pb), and/or titanium (Ti)), and/or alloys thereof. The barrier layer 515 may have a thin film shape having a single-layer or multilayer structure. The barrier layer 515 may include, for example, a first layer including titanium (Ti) and a second layer including copper (Cu).

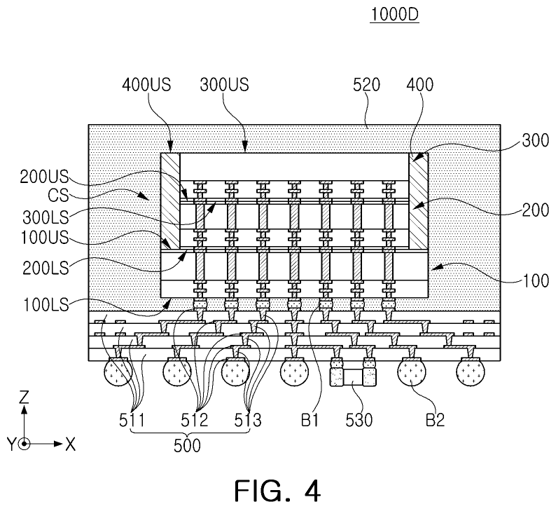

FIG. 4 is a cross-sectional view that illustrates a semiconductor package 1000D according to an embodiment of the present inventive concept.

Referring to FIG. 4, the semiconductor package 1000D according to the embodiment may have characteristics the same as or similar to those of the semiconductor packages 1000A and 1000B of FIGS. 1A to 3, except that a passive device 530 is mounted on the lower surface of the substrate 500. 1000C and may have the same or similar characteristics. The passive element 530 may include, for example, a capacitor such as a multilayer ceramic capacitor (MLCC) a low inductance chip capacitor (LICC), an inductor, a bead, and the like. In an embodiment, the passive element 530 may be a land-side capacitor (LSC). However, the present inventive concept is not limited thereto, and according to the embodiment, the passive element 530 may be a die- side capacitor (DSC) mounted on the upper surface of the substrate 500 or an embedded type capacitor built in the substrate 500.

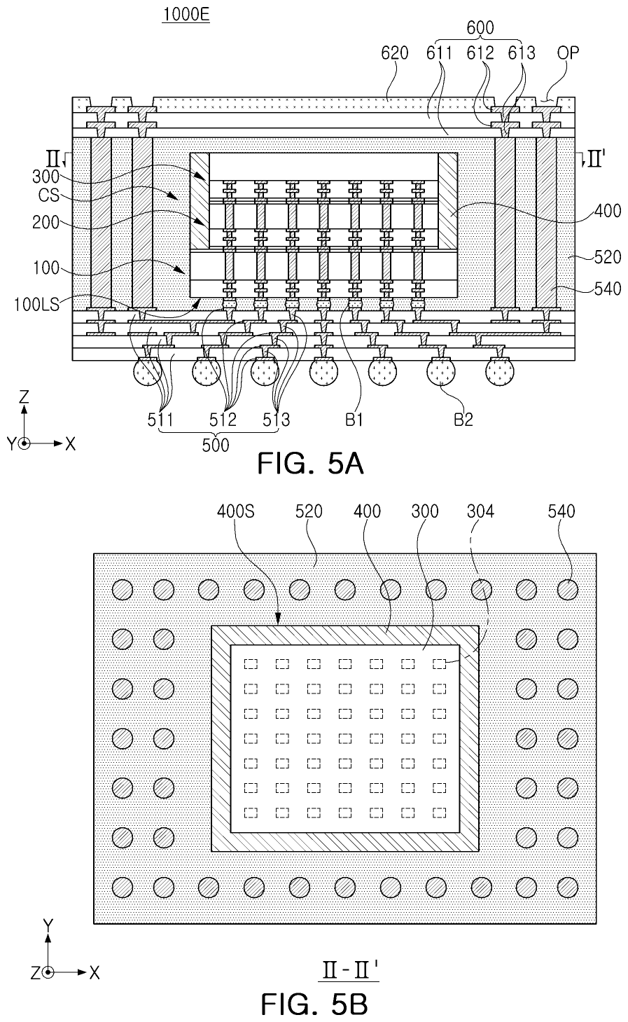

FIG. 5A is a cross-sectional view that illustrates a semiconductor package 1000E according to an embodiment of the present inventive concept, and FIG. 5B is a plan view that illustrates a cross-section taken along line II-II′ of FIG. 5A.

Referring to FIGS. 5A and 5B, a semiconductor package 1000E according to an example embodiment may have characteristics the same as or similar to those of the semiconductor packages 1000A, 1000B, 1000C, and 1000D of FIGS. 1A to 4, except that the semiconductor package 1000E further includes a redistribution structure 600 disposed on the second encapsulant 520 and a connection structure 540 electrically connecting the substrate 500 to the redistribution structure 600.

The connection structure 540 may be disposed around the chip structure CS on the substrate 500 and may be electrically connected to the first redistribution layer 512 of the substrate 500. The connection structure 540 may extend in a direction (e.g., the Z-axis direction), perpendicular to the upper surface of the substrate 500, within the second encapsulant 520, and an upper surface of the connection structure 540 may be exposed from the upper surface of the second encapsulant. For example, the second encapsulant 520 may have a post shape penetrating through the second encapsulant 520. However, the shape of the connection structure 540 is not limited thereto. The connection structure 540 may include a metal material, for example, copper (Cu), capable of electrically connecting the second redistribution layer 612 to the first redistribution layer 512. Accordingly, the connection structure 540 may provide an electrical connection path passing through the semiconductor package 1000E in a vertical direction.

The redistribution structure 600 may include a second insulating layer 611, a second redistribution layer 612 disposed on the second insulating layer 611, and a second redistribution via 613 electrically connecting the second redistribution layer 612 to the connection structure 540 through the second insulating layer 611. The second insulating layer 611 may be disposed on the upper surface of the second encapsulant 520. The second insulating layer 611 may include an insulating resin that includes the same or similar material to that of the first insulating layer 511 of the substrate 500. The second redistribution layer 612 and the second redistribution via 613 may include a metal material similar to that of the first redistribution layer 512 and the first redistribution via 513 of the substrate 500.

In addition, a cover layer 620 covering the second redistribution layer 612 and having an opening OP exposing at least a portion of the second redistribution layer 612 may be disposed in the redistribution structure 600. The cover layer 620 may be a solder resist layer that protects the uppermost second redistribution layer 612 from external contaminants as well as physical/chemical damage. The solder resist layer may include an insulating material and may be formed using, for example, prepreg, ABF, FR-4, BT, and/or photo solder resist (PSR).

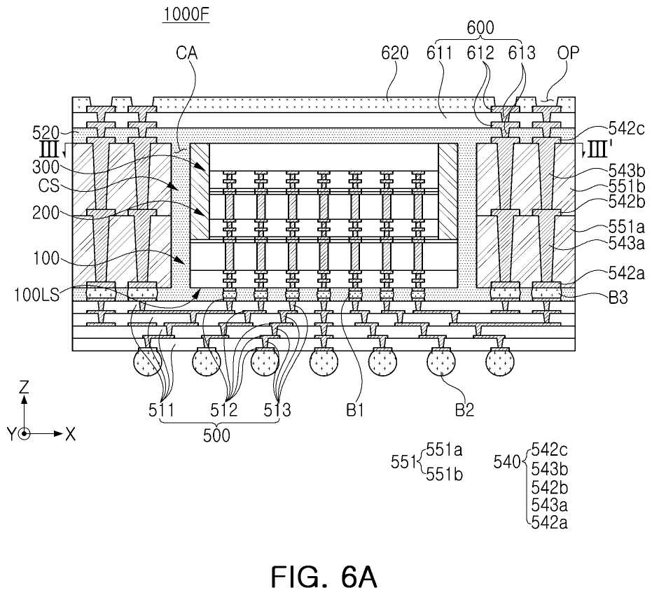

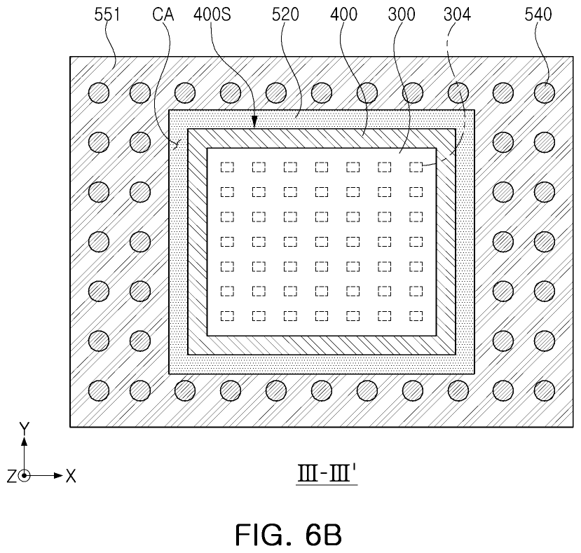

FIG. 6A is a cross-sectional view that illustrates a semiconductor package 1000F according to an embodiment of the present inventive concept, and FIG. 6B is a plan view that illustrates a cross-section taken along line of FIG. 6A.

Referring to FIGS. 6A and 6B, the semiconductor package 1000F according to the embodiment may have characteristics the same as or similar to those of the semiconductor packages 1000A, 1000B, 1000C, 1000D, and 1000E of FIGS. 1A to 5A, except that the semiconductor package 1000F further includes a frame structure 551 surrounding the connection structure 540. The frame structure 551 may have a cavity area CA in which the chip structure CS is accommodated, and may include one or more frame insulating layers 551a and 551b. The connection structure 540 may be disposed inside the frame structure 551, and may be electrically connected to the substrate 500 through the third connection bump B3 below the frame structure 551. The third connection bump B3 may be formed using, for example, a solder ball, but is not limited thereto. The frame structure 551 may increase rigidity of the semiconductor package 1000F according to a material of the frame insulating layers 551a and 551b, and may secure a thickness uniformity of the second encapsulant 520.

The frame insulating layers 551a and 551b may include an insulating material. As the insulating material, a thermosetting resin such as an epoxy resin, a thermoplastic resin such as polyimide, and/or a resin obtained by mixing these resins with an inorganic filler, e.g., ABF, may be used. Alternatively, a material in which the aforementioned resin is impregnated into glass fiber together with the inorganic filler, for example, a prepreg, may be used.

The connection structure 540 may include wiring layers 542a, 542b, and 542c disposed on the frame insulating layers 551a and 551b and wiring vias 543a and 543b penetrating through the frame insulating layers 551a and 551b. However, the shape and the constituent parts of the connection structure 540 applied to the present embodiment are not limited thereto, and the connection structure 540 may have a shape in the form of an extending post within the frame insulating layers 551a and 551b according to the embodiment.

The wiring layers 542a, 542b, and 542c may be electrically connected to the first redistribution layer 512 of the substrate 500 and may provide an electrical path passing through the semiconductor package 1000F in a vertical direction together with the wiring vias 543a and 543b. The wiring layers 542a, 542b, and 542c may include copper (Cu), aluminum (Al), silver (Ag), tin (Sn), gold (Au), nickel (Ni), lead (Pb), titanium (Ti), and/or alloys thereof. For example, the frame structure 551 may have a thickness greater than or equal to the chip structure CS, and a prepreg or the like may be selected as a material of the frame insulating layers 551a and 551b to maintain rigidity. Meanwhile, since the substrate 500 requires a fine circuit and high-density design, a photosensitive material (e.g., PID) may be selected as a material of the first insulating layer 511, and thus, a thickness of the wiring layers 542a, 542b, and 542c on the frame insulating layers 551a and 551b may be relatively thicker than a thickness of the first redistribution layer 512. The wiring vias 543a and 543b electrically connect the wiring layers 542a, 542b, and 542c formed in different layers, and as a result, an electrical path may be formed in the frame structure 551. The wiring vias 543a and 543b may include copper (Cu), aluminum (Al), silver (Ag), tin (Sn), gold (Au), nickel (Ni), lead (Pb), titanium (Ti), and/or alloys thereof. The wiring vias 543a and 543b may be field-type vias filled with a metal material or may be conformal-type vias in which a metal material is formed along a wall surface of a via hole.

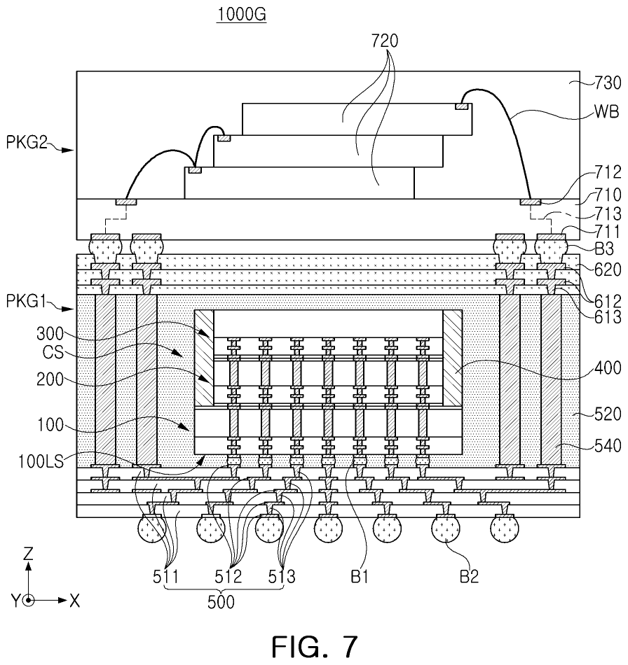

FIG. 7 is a cross-sectional view that illustrates a semiconductor package 1000G according to an embodiment of the present inventive concept.

Referring to FIG. 7, the semiconductor package 1000G according to an example embodiment may have a package-on-package (PoP) structure including a first package PKG1 and a second package PKG2. The first package PKG1 may have characteristics the same as or similar to those of the semiconductor packages 1000A, 1000B, 1000C, 1000D, 1000E, and 1000F described above with reference to FIGS. 1A to 6B.

The second package PKG2 may include a package substrate 710, a semiconductor chip 720, and a molding material 730. The package substrate 710 may include a lower pad 711 and an upper pad 712, which may be electrically connected to the outside (e.g., to components external to the package substrate 710), on a lower surface and an upper surface thereof, respectively. Also, the package substrate 710 may include a redistribution circuit 713 connected to the lower pad 711 and the upper pad 712 therein.

The semiconductor chip 720 may be mounted on the package substrate 710 by wire bonding or flip chip bonding. For example, the plurality of semiconductor chips 720 may be vertically stacked on the package substrate 710 and may be electrically connected to the upper pad 712 of the package substrate 710 by a bonding wire WB. As an example, the semiconductor chip 720 may include a memory chip such as volatile memory (e.g., DRAM), non-volatile memory (e.g., ROM and flash memory).

The molding material 730 may include a material the same as or similar to that of the second encapsulant 520 of the first package PKG1. The second package PKG2 may be physically and electrically connected to the first package PKG1 by a third connection bump B3. For example, the third connection bump B3 may be electrically connected to the redistribution circuit 713 through the lower pad 711 of the package substrate 710. The third connection bump B3 may include a low melting point metal, for example, tin (Sn) and/or an alloy including tin (Sn).

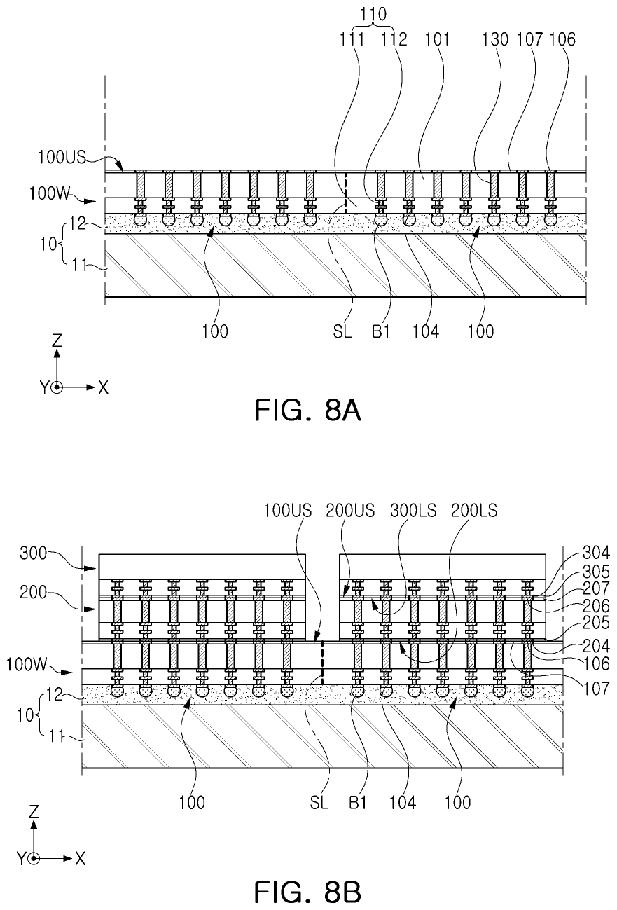

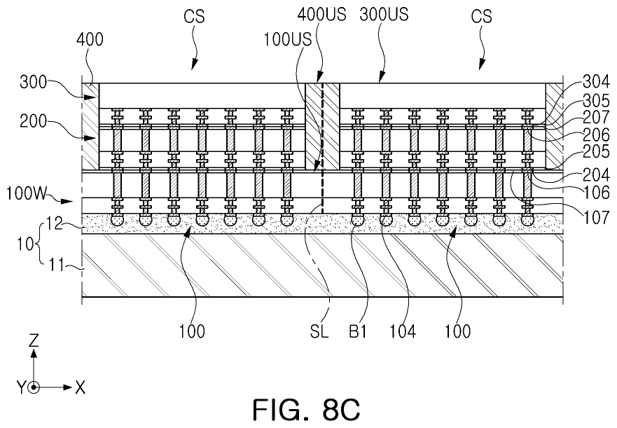

FIGS. 8A to 8C are cross-sectional views that illustrate a manufacturing process of a chip structure CS applied to a semiconductor package according to a process sequence of an example embodiment.

Referring to FIG. 8A, a semiconductor wafer 100W may be prepared. The semiconductor wafer 100W may include a plurality of first semiconductor chips 100 divided by a scribe lane SL. The semiconductor wafer 100W may be disposed on the carrier 10. The carrier 10 may include a support substrate 11 and an adhesive material layer 12. The semiconductor wafer 100W may be attached to the carrier 10 such that the lower surface on which the first connection bump B1 is disposed faces the adhesive material layer 12. The first connection bump B1 may be buried in the adhesive material layer 12, and a lower surface of the semiconductor wafer 100W may be in contact with an upper surface of the adhesive material layer 12. For example, side surface(s) of the first connection bump B1 may be surrounded by the adhesive material layer 12. The semiconductor wafer 100W may include a first upper pad 106 connected to an upper end of the first through-electrode 130 and a first upper dielectric layer 107 surrounding side surface(s) of the first upper pad 106. The upper surface 100US of the semiconductor wafer 100W or the first semiconductor chip 100 may include the upper surface of the first upper pad 106 and the upper surface of the first upper dielectric layer 107. The device layer 110 may include an interlayer insulating layer 111 and a multilayer wiring layer 112.

Referring to FIG. 8B, the second semiconductor chip 200 and the third semiconductor chip 300 may be sequentially stacked on the semiconductor wafer 100W. For example, before a cutting operation, the second semiconductor chip 200 may be implemented as a plurality of second semiconductor chips 200 disposed above the first semiconductor chip 100, and the third semiconductor chip 300 may be implemented as a plurality of third semiconductor chips 300 disposed above the second semiconductor chip(s) 200. The second lower surface 200LS of the second semiconductor chip 200 may be in direct contact with the first upper surface 100US of the first semiconductor chip 100, and the third lower surface 300LS of the third semiconductor chip 300 is the second. The second upper surface 200US of the semiconductor chip 200 may be in direct contact with the second upper surface 200US of the second semiconductor chip 200. Here, Cu to Cu bonding may be formed between the first upper pad 106 and the second lower pad 204, and oxide to oxide bonding may be formed between the first upper dielectric layer 107 and the second lower dielectric layer 205 surrounding them. Also, the same bonding structure may be formed between the second semiconductor chip 200 and the third semiconductor chip 300.

Referring to FIG. 8C, the first encapsulant 400 may be formed on the semiconductor wafer 100W. The first encapsulant 400 may be formed using EMC, for example. For example, the first encapsulant 400 may expose the upper surface 300US of the third semiconductor chip 300. Through a planarization process, the upper surface 400US of the first encapsulant 400 may be substantially coplanar with the upper surface 300US of the third semiconductor chip 300. The planarization process may be performed, for example, by a chemical mechanical polishing (CMP) process. Thereafter, the chip structures CS may be separated by cutting the first encapsulant 400 and the semiconductor wafer 100W along the scribe lane SL.

FIGS. 9A to 9D are cross-sectional views that illustrate a manufacturing process of a semiconductor package according to a process sequence of an example embodiment.

Referring to FIG. 9A, the substrate 500 and the connection structure 540 may be formed on the second carrier 20. The substrate 500 may be formed by building up the first insulating layers 511, the first redistribution layers 512, and the first redistribution vias 513 on the second carrier 20. The first insulating layers 511 may be formed, for example, by applying and curing a photosensitive resin. The first redistribution layers 512 and the first redistribution vias 513 may be formed using a photolithography process, an etching process, and a plating process. The connection structure 540 may be formed by patterning a photoresist film formed to have a predetermined height and then plating a metal material. The connection structure 540 may be formed on the uppermost first redistribution layer 512 or may be formed integrally with the uppermost first redistribution layer 512.

Referring to FIG. 9B, the chip structure CS may be mounted on the substrate 500 using a pick-and-place device 30. According to the present inventive concept, the chip structure CS having a predetermined thickness (about 200 μm or more) may be mounted on the substrate 500 in a flip-chip manner, thereby increasing the yield of the semiconductor package manufacturing process. Accordingly, the chip structure CS may be electrically connected to the first redistribution layer 512 through the first connection bump B1. The first connection bump BI may be attached to and fixed on the first redistribution layer 512 by a reflow process.

Referring to FIG. 9C, the second encapsulant 520 for encapsulating the chip structure CS may be formed on the substrate 500. The second encapsulant 520 may be formed by, for example, applying and curing EMC. In an embodiment, an underfill resin to be distinguished from the second encapsulant 520 may be formed between the chip structure CS and the substrate 500. For example, the second encapsulant 520 may have a molded underfill (MUF) shape filling a space between the chip structure CS and the substrate 500. The second encapsulant 520 may have a planarized upper surface using, for example, a CMP process, and the upper surface 540US of the connection structure 540 may be exposed through the upper surface of the second encapsulant 520.

Referring to FIG. 9D, a redistribution structure 600 may be formed on the second encapsulant 520. The redistribution structure 600 may be formed by building up the second insulating layers 611, the second redistribution layers 612, and the second redistribution vias 613 on the second encapsulant 520. The second insulating layers 611 may be formed, for example, by applying and curing a photosensitive resin. The second redistribution layers 612 and the second redistribution vias 613 may be formed using a photolithography process, an etching process, and a plating process. Thereafter, the second carrier 20 may be removed, and a second connection bump may be attached to the lower surface of the substrate 500, and additionally or alternatively a second package may be attached on the redistribution structure 600 as shown in FIG. 7. As described above, according to the present inventive concept, by mounting the chip structure CS having a predetermined thickness on the separately manufactured substrate 500, the chip structure CS may be redistributed through a fine-pitch redistribution circuit, and the yield of the semiconductor package including the chip structure CS may be increased.

According to embodiments of the present inventive concept, a semiconductor package including a chip structure in which a plurality of semiconductor chips are stacked may be provided.

In addition, by mounting the chip structure on a separately manufactured substrate, a high-performance semiconductor package with increased yield may be provided.

While example embodiments have been shown and described above, it will be apparent to those skilled in the art that modifications and variations may be made to the embodiments without departing from the scope of the present inventive concept as defined by the appended claims.

What is claimed is:

1. A semiconductor package comprising:
a substrate including a redistribution layer;
a chip structure including a first semiconductor chip disposed on the substrate and including a first through-electrode, a second semiconductor chip disposed on the first semiconductor chip and electrically connected to the first semiconductor chip by the first through-electrode, and a first encapsulant at least partially surrounding the second semiconductor chip;
a first connection bump disposed between the substrate and the chip structure and electrically connecting the first through-electrode to the redistribution layer;
a second connection bump disposed below the substrate and electrically connected to the redistribution layer; and
a second encapsulant encapsulating the chip structure on the substrate,
wherein the first semiconductor chip has a first upper surface on which a first upper pad is disposed and a first lower surface on which a first lower pad electrically connected to the first upper pad through the first through-electrode is disposed,
wherein the second semiconductor chip has a second lower surface on which a second lower pad electrically connected to the first upper pad is disposed, and
wherein the second lower surface of the second semiconductor chip is in direct contact with the first upper surface of the first semiconductor chip.

2. The semiconductor package of claim 1, wherein the first semiconductor chip has a width greater than a width of the second semiconductor chip in a first direction, wherein the first direction is parallel to an upper surface of the substrate.

3. The semiconductor package of claim 1, wherein the first encapsulant contacts at least a portion of the first upper surface of the first semiconductor chip and at least a portion of a side surface of the second semiconductor chip.

4. The semiconductor package of claim 1, wherein the second semiconductor chip has a second upper surface on which a second upper pad is disposed, and wherein the second semiconductor chip further includes a second through-electrode electrically connecting the second upper pad to the second lower pad.

5. The semiconductor package of claim 4, wherein the chip structure further includes a third semiconductor chip disposed on the second semiconductor chip, the third semiconductor chip having a third lower surface on which a third lower pad electrically connected to the second upper pad is disposed, and
wherein the third lower surface of the third semiconductor chip is in direct contact with the second upper surface of the second semiconductor chip.

6. The semiconductor package of claim 5, wherein the third upper surface of the third semiconductor chip is exposed from the first encapsulant.

7. The semiconductor package of claim 1, wherein the second encapsulant fills a space between the chip structure and the substrate and at least partially surrounds the first connection bump.

8. The semiconductor package of claim 1, wherein the second encapsulant contacts a side surface and an upper surface of the chip structure.

9. The semiconductor package of claim 1, wherein the second encapsulant has an interface with an upper and side surfaces of the first encapsulant, and wherein the interface contacts the upper and side surfaces of the first encapsulant.

10. The semiconductor package of claim 1, wherein the substrate further includes an insulating layer positioned on the second connection bump, and an under-bump metallization (UBM) structure penetrating through the insulating layer to electrically connect the redistribution layer disposed on the insulating layer to the second connection bump.

11. The semiconductor package of claim 10, wherein the UBM structure includes a UBM via penetrating through the insulating layer and a barrier layer disposed between a side surface of the UBM via and the insulating layer.

12. A semiconductor package comprising:
a substrate including a redistribution layer;
a chip structure including a plurality of semiconductor chip disposed on an upper surface of the substrate and stacked in a direction perpendicular to the upper surface of the substrate, and a first encapsulant surrounding a side surface of one or more semiconductor chips of the plurality of semiconductor chips;
a connection bump disposed between the substrate and the chip structure and electrically connecting the plurality of semiconductor chips to the redistribution layer; and
a second encapsulant encapsulating the chip structure on the substrate,
wherein the chip structure has a lower surface spaced apart from the upper surface of the substrate, and
wherein the second encapsulant fills a space between the lower surface of the chip structure and the upper surface of the substrate and surrounds a side surface of the connection bump.

13. The semiconductor package of claim 12, wherein the first and second encapsulants include the same type of insulating material.

14. The semiconductor package of claim 12, wherein the upper surface of the chip structure includes an upper surface of the first encapsulant and an upper surface of an uppermost semiconductor chip among the plurality of semiconductor chips.

15. The semiconductor package of claim 12, wherein the chip structure has an upper surface opposite to the lower surface of the chip structure and a side surface extending between the lower surface of the chip structure and the upper surface of the chip structure, and
wherein the second encapsulant covers the upper surface and the side surface of the chip structure.

16. The semiconductor package of claim 12, wherein the chip structure has a height of about 200 μm or greater in the direction perpendicular to the upper surface of the substrate.

17. The semiconductor package of claim 12, wherein one or more semiconductor chips of the plurality of semiconductor chips includes a through-electrode, and
wherein the plurality of semiconductor chips are electrically connected to each other through the through-electrode.

18. A semiconductor package comprising:
a substrate including a first redistribution layer;
a chip structure including a plurality of semiconductor chips disposed on an upper surface of the substrate and stacked in a direction, perpendicular to the upper surface of the substrate, and a first encapsulant surrounding a side surface of one or more semiconductor chips of the plurality of semiconductor chips;
a connection bump disposed between the substrate and the chip structure and electrically connecting the plurality of semiconductor chips to the redistribution layer;
a second encapsulant covering an upper surface and a lower surface of the chip structure;
a redistribution structure including an insulating layer disposed on the second encapsulant, and a second redistribution layer on the insulating layer; and
a connection structure penetrating through the second encapsulant to electrically connect the first redistribution layer to the second redistribution layer.

19. The semiconductor package of claim 18, wherein the redistribution structure further includes a redistribution via penetrating through the insulating layer to electrically connect the second redistribution layer to the connection structure.

20. The semiconductor package of claim 18, further comprising:
a cover layer covering the second redistribution layer and disposed on the redistribution structure and having an opening exposing at least a portion of the second redistribution layer.
